(19) United States
(12) Patent Application Publication
(10) Pub. No.: US 2021/0241998 A1
(43) Pub. Date: Aug. 5, 2021

(54) PLASMA PROCESSING APPARATUS AND INNER COMPONENT OF PLASMA PROCESSING APPARATUS AND MANUFACTURING METHOD OF INNER COMPONENT OF PLASMA PROCESSING APPARATUS

(71) Applicant: HITACHI HIGH-TECHNOLOGIES CORPORATION, Tokyo (JP)

(72) Inventors: Tomoyuki TAMURA, Tokyo (JP); Kazuyuki IKENAGA, Tokyo (JP)

(73) Assignee: Hitachi High-Technologies Corporation, Tokyo (JP)

(21) Appl. No.: 16/646,917

(22) PCT Filed: Apr. 12, 2019
(86) PCT No.: PCT/JP2019/015912

§ 371 Date: Mar. 12, 2020

(51) Int. Cl. H01J 37/32

(52) U.S. Cl. CPC H01J 37/32495

(57) ABSTRACT

There is provided a plasma processing apparatus that suppress the contamination of a sample and improves process yield or an inner component of a plasma processing apparatus or a manufacturing method for the inner component. A plasma processing apparatus processes a wafer which is a processing target placed in a processing chamber in an inside of a vacuum chamber using plasma formed from a processing gas supplied to an inside of the processing chamber. A surface of a component that is placed in the inside of the processing chamber and faces the plasma is made of a dielectric material. The dielectric material includes a first material that combines with the supplied processing gas and is volatilized and a second material that combines with the processing gas to produce a non-volatile compound, a volume of the non-volatile compound being increased before the combination.

### TECHNICAL FIELD

The present invention relates to a plasma processing apparatus that processes a substrate-shaped sample, such as a semiconductor wafer, which is a processing target, in a processing chamber placed in the inside of a vacuum chamber using plasma formed in the processing chamber, to the inner component of the processing chamber, or a manufacturing method for an inner component of the processing chamber, and particularly to an inner component of a processing chamber having a coating on a surface facing plasma against plasma and a plasma processing apparatus equipped with an inner component or a manufacturing method for an inner component.

### BACKGROUND ART

As an example of the technique of a plasma processing apparatus having a coating on the surface of the inner component of a processing chamber, the inner component being placed in the inside of the processing chamber and exposed to plasma, one that is disclosed in Japanese Unexamined Patent Application Publication No. 2007-321183 (Patent Literature 1) is conventionally known. In this conventional technique, a plasma processing apparatus is disclosed, in which a component is placed in the inside of a processing chamber, in which plasma is formed, the component has a coating on the surface of a part that is exposed to plasma, and the coating is made of a dielectric material, such as ceramics, including Y₂O₃ as a principal component and SiO₂ (silicon oxide) at 0.2 to 5.0% as a component, and the coating has a thickness in a value in the range of 10 to 500 μm.

The present conventional technique describes that the coating on the surface of the component in the processing chamber is formed by thermal spraying of granulated powder, as the raw material of the coating, that is a dielectric material including Y₂O₃, which is a principal component, and SiO₂ at 0.2 to 5.0%. Moreover, the present conventional technique also discloses the point that as a coating, a multi-layer film is provided, in which a plurality of types of films made of a material having different compositions is stacked.

### CITATION LIST

### Patent Literature

Patent Literature 1: Japanese Unexamined Patent Application Publication No. 2007-321183

### SUMMARY OF INVENTION

### Technical Problem

However, a problem arises in the conventional technique because consideration is insufficiently paid to the point below. That is, the dielectric material forming the coating on the surface of the component, which is placed in the inside of the processing chamber and exposed to plasma, is affected by the action from charged particles or particles having high reactivity in plasma, at least a part of the dielectric material forms another substance (compound) by combining with these particles and the material of the surface of the coating is altered to another material, i.e., the surface is a so-called altered surface.

Depending on the processing conditions, such as the composition of predetermined mixed processing gasses or pressures in a processing chamber, under which a processing target is a film layer in a film structure having a plurality of film layers, which is formed in advance on the top surface of a sample and processed for forming the circuit structure of a semiconductor device, such compounds of altered surface also include compounds whose crystal grain size is increased before and after the combining. The crystal grain size is increased on the surface of the coating and just below the surface, and the size of the film are increased more than the lower part of the coating where no combining occurs, or distortion is produced between grains whose grain size is increased to cause stress. Such an increase in the dimensions of the film or in stress causes a risk that cracking or chipping on the surface of the coating or in the inside of the coating, fragments fly in the processing chamber, and are attached to other places, specifically to the surface of the sample, resulting in occuring contamination particles on the sample surface.

In the conventional technique, no consideration is paid to a problem that due to a contamination particle produced from such alteration of the surface of the component in the inside of the processing chamber, the sample is contaminated, and process yield decreases.

An object of the present invention is to provide a plasma processing apparatus that suppresses the contamination of a sample and improves process yield or an inner component of a plasma processing apparatus or a manufacturing method for the inner component.

### Solution to Problem

The above-described problem can be solved in which a material at least on the surface of a component having a surface of an oxide brittle material is a mixture of a first oxide material that reacts to fluorine to have volatility or sublimation and a second oxide material that reacts to fluorine to have non-volatility, and the content of the first oxide material is set in a predetermined range. Here, a predetermined range of the first oxide material is the rate of the volume increase when the second oxide material is chemically changed from oxide to fluoride or fluorinated oxide.

More specifically, the object is achieved by a plasma processing apparatus that processes a wafer which is a processing target placed in a processing chamber in an inside of a vacuum chamber using plasma formed from a processing gas supplied to an inside of the processing chamber. In the apparatus, a surface of a component that is placed in the inside of the processing chamber and faces the plasma is made of a dielectric material. The dielectric material includes a first material that combines with the supplied processing gas and is volatilized and a second material that combines with the processing gas to produce a non-volatile compound, a volume of the non-volatile compound being increased before the combination.

The object is achieved by a manufacturing method for an inner component that is placed in a processing chamber in an inside of a vacuum chamber of a plasma processing apparatus that processes a wafer that is a processing target using plasma formed from a processing gas supplied to an inside of the processing chamber. In the method, on a surface of the inner component, a dielectric material is formed in advance, the dielectric material including a first material that combines with the supplied processing gas and is volatilized and a second material that combines with the processing gas to produce a non-volatile compound, a volume of the non-volatile compound being increased before the combination.

### Advantageous Effects of Invention

According to the present invention, a plasma processing apparatus that suppresses the contamination of a sample and improves process yield or an inner component of a plasma processing apparatus or a manufacturing method for the inner component can be provided.

### BRIEF DESCRIPTION OF DRAWINGS

FIGS. 1(a) and 1(b) are longitudinal sectional views schematically showing the outline of the configuration of a plasma processing apparatus according to an embodiment of the present invention.

FIGS. 2(a) and 2(b) are longitudinal sectional views schematically showing the outline of the configuration of a coating according to a conventional technique.

FIGS. 3(a) and 3(b) are longitudinal sectional views schematically showing the outline of the configuration of a coating provided in the plasma processing apparatus according to the present embodiment shown in FIG. 1.

FIG. 4 is a table showing proper ranges of amounts at which a first material having volatility is mixed with a plurality of second materials having non-volatile oxide and non-volatile fluoride in materials that forms the coating of the plasma processing apparatus according to the present embodiment shown in FIG. 1.

FIG. 5 is a table showing the physical properties of a plurality of first materials that the proper ranges are shown in FIG. 4 in which the pressure of volatile fluoride becomes a vapor pressure greater than a predetermined pressure in a processing chamber.

### DESCRIPTION OF EMBODIMENTS

In the following, an embodiment of the present invention will be described with reference to the drawings.

### Embodiment

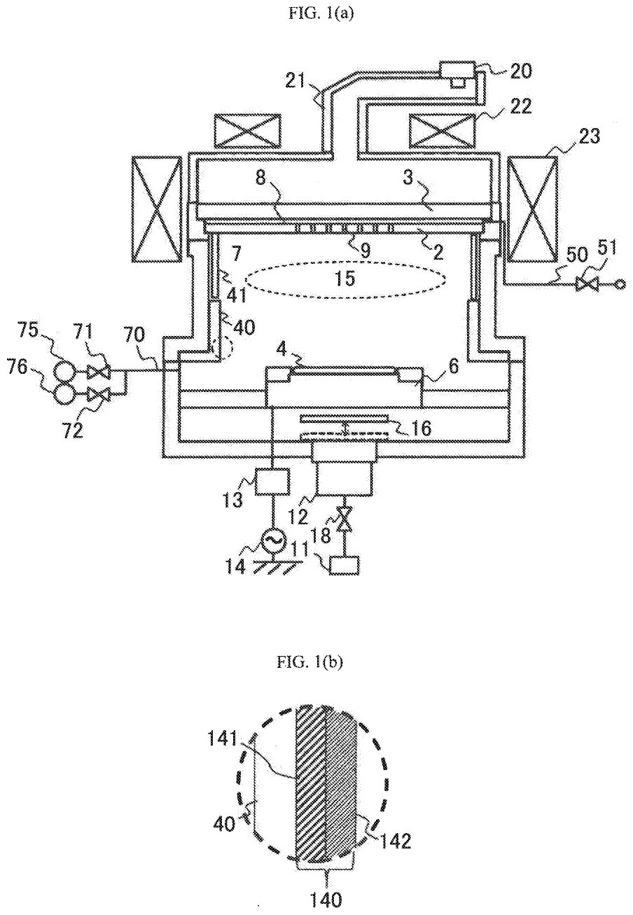

In the following, an embodiment of the present invention will be described with reference to FIGS. 1(a) to 5.

FIGS. 1(a) and 1(b) are longitudinal sectional views schematically showing the outline of the configuration of a plasma processing apparatus according to an embodiment of the present invention. Specifically, a plasma processing apparatus 100 according to the present embodiment described in FIG. 1(a) has a processing chamber 7 that is a space, in which plasma 15 is formed, in the inside of a vacuum chamber 1 partially having a cylindrical shape. The plasma processing apparatus 100 is a plasma etching apparatus in which a wafer 4 is placed on the top surface of the center part of the upper part of a sample stage 6 placed on the processing chamber 7 at a reduced pressure, a film structure is formed in advance on the top surface of wafer 4, the film structure is composed of a plurality of film layers including a mask layer that is a film layer in the upper part, and a film layer that is a film layer in the lower part and is a processing target is etched with the plasma 15.

On the inner side of a side wall part 42 in a partially cylindrical shape provided in the upper part, the processing chamber 7 has a discharge part that is a space in which the plasma 15 is formed. In the processing chamber 7, an earth component 40 and an inner cylinder 41 made of silica glass are included. The earth component 40 surrounds the discharge part in a ring shape or cylindrically surrounds the discharge part and is placed covering the lower part of the inner circumferential wall surface of the side wall part 42 to the discharge part. The inner cylinder 41 having a cylindrical shape is placed above the earth component 40, and the inner cylinder 41 is placed covering the lower part of the inner circumferential wall surface of the side wall part 42 to the discharge part. Above the upper end part of the inner cylinder 41, a shower plate 2 made of a dielectric material like silica glass is placed. The shower plate 2 has a disk shape, constitutes the ceiling surface of the processing chamber 7, and has a plurality of processing gas inlet holes 9 placed on its center part. On the upper part spaced at a gap 8 from the top surface of the shower plate 2, a window component 3 made of silica glass is placed. The window component 3 is a disk-shaped component placed on a top end ring 10 made of metal placed on the top end of the side wall of the vacuum chamber 1, and the window component 3 constitutes the vacuum chamber 1.

FIG. 1(b) schematically shows an enlarged outline of the configuration of the earth component 40 at one place indicated by a broken line circle in FIG. 1(a) as a longitudinal section. The earth component 40 according to the present embodiment includes a coating 140 on the surface on the inner circumferential side. The surface faces at least the processing chamber 7 and contacts the plasma 15. The coating 140 covers the surface, and made using a material of relatively high resistance to interactions received from the particles of the plasma 15. The earth component 40 according to the present embodiment has an L-shape in its longitudinal section, and includes the coating 140, at least on the inner circumferential side wall, the under surface, and the top surface of the upper end part of the inner circumferential side wall. The lower end part of the inner cylinder 41 made of silica glass is placed on the upper end part of the inner circumferential side wall of the earth component 40. The inner cylinder 41 is spaced from the surface of the inner circumferential side wall of the side wall part 42 on upper part of the vacuum chamber 1 in a cylindrical shape with a gap, and placed covering the surface of the inner circumferential side wall.

Note that the area of the surface of the earth component 40 that faces or contacts the plasma 15 is twice the size of the area of the top surface of the wafer 4 on the sample stage 6. The area of the inner circumferential side wall of the inner cylinder 41 in a cylindrical shape that faces or contacts the plasma 15 is a value greater than the value of the area of the top surface of the wafer 4.

In the present embodiment, the coating 140 has a configuration in which a plurality of film layers is stacked above and below the boundary surface, and as a base layer that is a film layer in the lower part, an under layer film 141 is formed in a thickness of 150 μm having Y₂O₃ as a material. The under layer film 141 of the present embodiment is formed by flame spray coating by which a Y₂O₃ particle having a predetermined composition is semi-molten by plasma at a high temperature and is sprayed to the surface that is a coating target.

On the top surface of the under layer film 141, a surface film 142 is formed in a thickness of 50 μm. The surface film 142 has a mixing ratio that is a ratio of Y₂O₃ to SiO₂=100:23 (volume ratio) as a material having Y₂O₃ mixed with SiO₂ as a principal component. The crystal grain size of Y₂O₃ of the surface film 142 that is made using Y₂O₃ mixed with SiO₂ as a material is 200 nm or less, and the SiO₂ component is mainly present on the grain boundary. The surface film 142 of the present embodiment does not include Al, Zr, Cr, Hf, Ta, Ti, and the other metals at 1,000 ppm or more.

Above the window component 3 of the vacuum chamber 1 and above the processing chamber 7, the lower end part of a waveguide 21 is placed being joined to the processing chamber 7. Through the inside of the waveguide 21, a microwave electric field at a frequency of 2.45 GHz propagates, which is supplied in the processing chamber 7 for generating the plasma 15 in the discharge part of the processing chamber 7. The waveguide 21 has a hollow part, a cylindrical part, and a square part. The hollow part has a cylindrical shape in a diameter having an equal value to the diameter of the window component 3 or a diameter in approximation almost regarded as the diameter of the window component 3, and the hollow part is sandwiched between the window component 3 and the cylindrical part. The cylindrical part is placed above the hollow part, the cylindrical part has a diameter smaller than the diameter of the hollow part in a circular shape in a cross section, and the axis vertically extends. One end part of the square part is connected to the upper end part of the cylindrical part, the square part has a rectangle or a square in a cross section, and the axis horizontally extends. On the other end part of the square part of the waveguide 21, a power supply 20, such as a magnetron, that oscillates and forms a microwave electric field is provided.

On the outer side of the cylindrical part of the waveguide 21 and on the outer side of the hollow part below the cylindrical part and the side wall on the upper part of the vacuum chamber 1 surrounding the discharge part of the processing chamber 7, a plurality of coils 22 and 23 is vertically placed surrounding these components in a ring shape. The coils 22 and 23 that form a plurality (two in the embodiment) of stages is supplied with a direct current, and generates a magnetic field. In the inside of the processing chamber 7, a magnetic field is formed, which has magnetic lines of force extending in symmetry about the vertical center axis of the discharge part or the shower plate 2.

In the inside of the sample stage 6, a base material made of metal in a disk shape or a cylindrical shape is provided. The base material has a center axis at a position concentric to the vertical center axis of the discharge part or the processing chamber 7 or a position in approximation almost regarded as the vertical center axis. The base material has a shape in which the center part of the upper part is raised higher than the outer circumferential part and the longitudinal section is in a projecting shape, and the base material has a lower part in a ring shape with a step on the outer circumferential side. The top surface of the raised center part and the top surface of the step part are covered with an adsorption film that is a coating made of a dielectric material including alumina or yttria. In the inside of the adsorption film on the top surface of the center part, a film-shaped electrode supplied with direct current power is made. Direct current power is supplied such that different polarities are imparted to a plurality of film-shaped electrodes in the state in which the wafer 4 is placed on the adsorption film on the top surface of the center part, and the wafer 4 is adsorbed and held in the direction of the film on the lower part.

A bias electrode or a base material that is another film-shaped electrode is placed in the inside of the adsorption film is electrically connected to a radio frequency power supply 14 that supplies radio frequency power at a frequency of 800 MHz or less. The radio frequency power supply 14 is connected through a power supply passage formed including a coaxial cable in a bias electrode and through a matching circuit 13 placed on the power supply passage. During processing of the wafer 4, radio frequency power is supplied to the bias the electrode or the base material, and a bias potential having a potential difference is formed between above the top surface of the wafer 4 and the plasma 15 formed in the discharge part. The radio frequency power supply 14 of the present embodiment supplies radio frequency power of 500 W or less per unit area of the wafer 4 in a diameter of 300 mm to the base material or the bias electrode, and a radio frequency bias voltage formed by radio frequency power is used under the conditions in which the amplitude (Vpp) is 800 V or less.

The sample stage 6 of the present embodiment at least partially in a cylindrical shape is placed in the center part of the processing chamber 7 in the horizontal direction viewed from above. The outer circumferential side wall is connected to the vacuum chamber 1 through a plurality of support beams whose horizontal axis extends across a side wall component on the lower part of the vacuum chamber 1. The side wall component constitutes the inner circumferential side wall of the processing chamber 7. With this configuration, the sample stage 6 is held in the center part of the processing chamber 7 in the height direction, and the discharge part is provided between the top surface of the sample stage 6 and the shower plate 2 above the sample stage 6,

and a space, into which a gas or plasma particles from the discharge part flow through a clearance between the support beams between the outer circumferential side wall of the sample stage 6 and the side wall of the processing chamber 7, is formed below the sample stage 6 between the bottom surface of the sample stage 6 and an exhaust opening placed in the center part of the bottom surface of the processing chamber 7 in the horizontal direction.

Below the vacuum chamber 1, a turbo molecule pump 12 is placed being is joined to the bottom surface of the vacuum chamber 1, and the inlet of the turbo molecule pump 12 communicates with the exhaust opening placed in the center part of the bottom surface of the processing chamber 7 in the vacuum chamber 1. The outlet of the turbo molecule pump 12 is connected with a roughing vacuum pump 11, such as a rotary pump, through a pipe.

On the bottom part of the processing chamber 7, an exhaust valve 16 in a disk shape is placed. The exhaust valve 16 vertically moves to the exhaust opening, that hermetically seals the inside and the outside with surrounds the outer periphery of the exhaust opening at a position at the lower end. In the exhaust valve 16, a plurality of places on the outer edge of the bottom surface is connected to a drive unit, not shown, such as an actuator, joined to the bottom surface below the bottom surface of the vacuum chamber 1. The exhaust valve 16 is configured in which the operation of the drive unit vertically moves the exhaust valve 16 to the exhaust opening or the outer edge of the exhaust opening to change a distance, and the exhaust valve 16 can variably adjust the exhaust area of a gas or particles from the exhaust opening.

The plasma processing apparatus 100 of the present embodiment includes an exhaust system composed of the roughing vacuum pump 11, the turbo molecule pump 12, and the exhaust valve 16. In the state in which the exhaust valve 16 is present above the exhaust opening and the distance of the exhaust valve 16 to the exhaust opening is adjusted to a predetermined value, by the operation of the exhaust system of the turbo molecule pump 12 and the roughing vacuum pump 11, the particles in the space below the sample stage 6 in the processing chamber 7 are discharged from the exhaust opening to the outside of the vacuum chamber 1.

To a top end ring 10 made of metal placed above the top end of the side wall part 42, which constitutes the upper part of the vacuum chamber 1, at least a part of which has a cylindrical shape, a pipe 50 is connected, in the inside of which a processing gas or an inert gas to be introduced into the gap 8 between the shower plate 2 and the window component 3 is conducted. The pipe 50 constitutes a gas supply passage through which a processing gas or an inert gas is supplied to the inside of the processing chamber 7. In the present embodiment, the gas supply system is constituted including the gas supply passage, at least one flow controller 51, such as a mass flow controller (MFC) that is placed on the gas supply passage and adjusts the flow rate or speed of a gas flowing in the inside, and a gas source 52 of a processing gas or an inert gas.

In the present embodiment, a processing gas or an inert gas passed from the gas supply system through the pipe 50, passed through a through passage in the inside of the top end ring 10, and introduced into the gap 8 is diffused in the inside of the gap 8, passed through a plurality of gas inlet holes 9, and introduced into the inside of the processing chamber 7 from above the wafer 4 placed and held on the sample stage 6 or the top surface of the sample stage 6. The exhaust valve 16 is configured in which adjusting the vertical motion and the distance to the exhaust opening adjusts the exhaust amount of a gas or particles supplied from the inside of the processing chamber 7, and based on the balance between the exhaust amount and the supply amount of a gas introduced from the gas supply system into the inside of the processing chamber 7 through the gas inlet holes 9, the pressure in the inside of the processing chamber 7 and the pressure specifically on the top surface of the wafer 4 or the pressure in the discharge part above are adjustable to values in a proper range for processing.

In order to detect the pressure in the processing chamber 7, the plasma processing apparatus 100 has a pressure gage 72 with ability to connect with the inside of the processing chamber 7. The pressure gage 72 is joined to a pipe 70 that detects pressures and is connected to an opening on an inner side wall surrounding the outer side wall of the sample stage 6 in the processing chamber 7, and on the pipe 70, a valve 71 that opens and closes the connection of the pipe 70 is placed. In detecting the pressure in the processing chamber 7, the valve 71 is opened to connect with the inside of the pipe 70. In the case in which it is necessary to suppress the access of the particles to the pressure gage 72, the valve 71 is closed. The particles are the particles of the plasma 15 in the processing chamber 7 or reaction products produced during processing of the wafer 4.

The plasma processing apparatus 100 of the present embodiment includes a controller, not shown, that adjusts the operation of the plasma processing apparatus 100 to be expected. The controller is configured in which the controller is communicably connected to the turbo molecule pump 11, the roughing vacuum pump 12, the matching circuit 13, the radio frequency power supply 14, the drive unit of the exhaust valve 16, the flow controller 51, the power supply 20, the coils 22 and 23, the valve 71, the pressure gage 72, and any other components, and the controller receives signals including information from these components to detect the state of the operation, and sends signals to instruct the components to operate. The controller is configured in which the controller can also send signals of loading and unloading of the wafer 4 to and from the processing chamber 7 by the plasma processing apparatus 100, the detection or determination of the stat and end of processing of the wafer 4, and the determination of necessity of processing a subsequent wafer 4 and signals to instruct these operations, and the controller is operable to adjust the operation by the plasma processing apparatus 100.

Next, the outline of the process of the wafer 4 by the plasma processing apparatus 100 of the present embodiment will be described. An unprocessed wafer 4 that is not subjected to processing by the plasma processing apparatus 100 is held on a robot arm for transport in a vacuum transport chamber in the inside of a vacuum transport chamber at a reduced pressure, which is another vacuum chamber 1 connected to the vacuum chamber 1 on the outer side. The robot arm is placed in the inner transport chamber. The unprocessed wafer 4 is loaded to the inside of the processing chamber 7 whose pressure is reduced to a value equivalent to the pressure in the vacuum transport chamber through a gate that connects between the vacuum transport chamber and the processing chamber 7. The gate is a passage for the wafer 4. The wafer 4 is delivered from a wafer holding hand at the arm tip end part of the robot arm to the sample stage 6, the arm is retracted from the processing chamber 7 to the vacuum transport chamber, the gate is then closed by an opening and closing valve, not shown, and the inside of the processing chamber 7 is hermetically sealed.

After that, the wafer 4 is electrostatically chucked and held on the adsorption film by electrostatic force that has occurred due to direct current power applied to the film-shaped electrode in the adsorption film on the top surface of the sample stage 6. Between the top surface of the adsorption film and the back surface of the wafer 4 held on the adsorption film, a gas of the heat transfer properties, such as He, is supplied to promote the heat transfer between the wafer 4 and the sample stage 6, and the exhaust valve 16 moves above and is held at the top end position, and then the pressure in the inside of the processing chamber 7 is reduced to a predetermined high vacuum degree.

A processing gas is introduced from the gas supply system into the processing chamber 7 through the flow controller 51 and the pipe 50, the passage area of the exhaust opening is adjusted by the operation of the exhaust valve 16 corresponding to the pressure detected by the pressure gage 72, and the inflow of the processing gas to the processing chamber 7 is balanced to the exhaust amount from the exhaust opening to adjust the pressure in the processing chamber 7 to a value within the range suited to the process of the wafer 4. In the present embodiment, the inside of the processing chamber 7 is configured in which the pressure is adjusted in the range of values from 0.1 Pa to 10 Pa. Note that before and after the process of the wafer 4, the distance of the exhaust opening (the distance between the opening edges) of the exhaust valve 16, and the processing chamber 7 is evacuated at 0.01 Pa or less.

The process of the wafer 4 using plasma according to the present embodiment is conducted in multiple steps in which a plurality of steps is continuously performed. In the steps, at least one type or more gases including one kind or more elements in Cl, F, C, O, S, N, Ar, H, Br, B, and He as a processing gas to be introduced into the inside of the processing chamber 7. For example, the process of the wafer 4 is performed by the step of suppling a processing gas including Cl₂ to the inside of the processing chamber 7 to form the plasma 15 for processing the processing target film of the wafer 4, the step of forming the plasma 15 for processing using a processing gas including CF₄, the step of forming the plasma 15 for processing using a processing gas including 02, and the step of forming the plasma 15 for processing using a processing gas including SF₆.

The coating 140 has Ra (a so-called, the arithmetic average roughness) of its surface at 0.5 μm or more 8 μm or less. Prior to starting the process of the wafer 4 for mass-producing semiconductor devices, the material that makes the surface of the coating 140 may be fluorinated by exposing to the plasma 15 for a predetermined time period by performing in which the plasma 15 is formed using a processing gas including a fluorine gas introduced into the inside of the processing chamber 7.

In the present embodiment, the composition of the surface film 142 that has a principal component of Y₂O₃ mixed with SiO₂ as a dielectric material was determined as below. That is, the inventors placed a component having a coating using a dielectric material including Y₂O₃ in the inside of the processing chamber 7, performed the operation of the plasma processing apparatus 100 for a predetermined period in which the wafer 4 was processed under predetermined conditions using plasma 15 including one kind or two kinds or more of SF₆, O₂, Ar, NF₃, Cl₂, CF₄, and CHF₃, checked the volume or dimensions of the crystal grain of Y₂O₃ that makes the coating using an SEM (Scanning Electron Microscope), and detected the size of expansion of the particle and the rate, compared with those before starting the operation.

As a result, under the processing conditions, the rate of expansion of the Y₂O₃ crystal grain in the lateral direction was 7%. This corresponds to an increase of 23% in the volume of the particle. From this, in the material of the surface film 142 of the present embodiment, the rate of Y₂O₃ to SiO₂ that make up the material was set to 100:23 (volume ratio). Here, the volume means the crystal grain of the material, and does not include pores or gaps formed in the inside of the coating 140. In the surface film 142 of the present embodiment, weights corresponding to the volumes of the materials at the mixing ratio were converted from the density, and Y₂O₃ and SiO₂ as materials were mixed such that the weight ratio of Y₂O₃ to SiO₂ was 100:10.

With the configuration, when the earth component 40 having the surface film 142 formed by mixing Y₂O₃ with SiO₂ of the present embodiment on its surface is placed in the processing chamber 7 and the operation of processing the wafer 4 is performed, Si components volatilize from the surface of the surface film 142 for desorption. Thus, an increase in the dimensions of the surface film 142 as a film due to the fluorination and expansion of the Y₂O₃ particle is cancelled or reduced, and the cracking or chipping of the surface of the surface film 142 due to an increase in stress on the surface and in the inside and due to an increase in the stress is reduced or is suppressed. Cracking or chipping in smaller size is suppressed, as SiO₂ components are more densely dispersed. In the present embodiment, since the SiO₂ crystal grain as a material is present between the Y₂O₃ particles (on the grain boundary), cracking in dimensions greater than the dimensions of the Y₂O₃ crystal grain is not generated. Thus, the generation of contamination particles in association with cracking can be reduced.

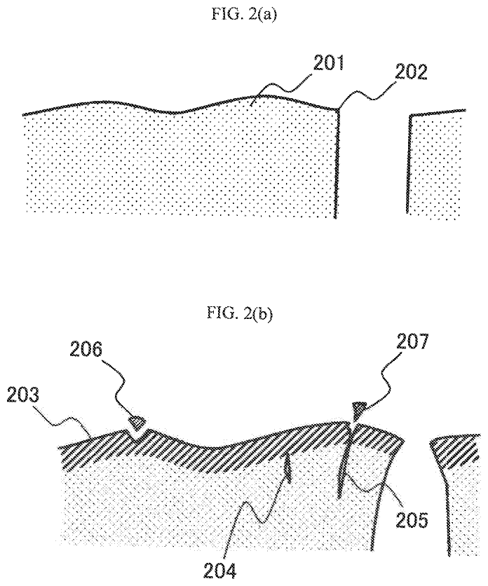

Referring to FIGS. 2(a) and 2(b), the mechanism of generating cracking due to the accumulation of stress on the ceramic surface will be described. FIGS. 2(a) and 2(b) are longitudinal sectional views schematically showing the outline of the configuration of a coating according to a conventional technique. FIG. 2(a) is a view showing the longitudinal section of the coating in the beginning at which the operation is started in which an inner component having the coating formed on the surface is placed in a processing chamber 7 to process a wafer 4. FIG. 2(b) is a view showing the longitudinal section of the coating after a point in time when the operation is performed for a period of a predetermined value or more.

The in-plane stress of the surface of the ceramics material to a depth of a few micrometers from the surface can be checked by X-rays diffraction. Typically, fluorine has an electronegativity higher than the electronegativity of oxygen and has a large binding energy to a metal, a surface 201 of an oxide ceramics material faces fluorine plasma to develop fluorination, and an altered layer 203 including fluoride is formed. Since a stable valence of oxygen that can take is divalent and a stable valence of fluorine is monovalent, the total atom number of oxygen and fluorine per metal atom is increased, and the crystal grain of the material including fluoride and the altered layer 203 made up of the material expands. In actual component surface, the surface is not an ideal flat surface throughout the surface, and the surface can expand at a portion 202 having micro irregularities.

In the case of the coating formed by the conventional technique, supposing that the surface is altered (fluorinated) by fluorine and expand by 1%, a deformation less than 1%, 0.5%, for example, occurs right below the altered layer 203. The Young's modulus of many ceramics materials ranges from 100 GPa to 400 GPa. For example, in the case of a material whose Young's modulus is 160 GPa, a tensile stress of 0.8 GPa is applied when the material is not cracking in calculation. Although the altered layer 203 on the surface is suffered from compressive stress, the compression strength of the ceramics material is typically 15 times the tension strength or more. The place right below the altered layer to which the tensile stress is applied is prone to be relatively broken.

The tensile strength of the ceramics material depends on the defect, crack, or the like of the crystal, and the tensile strength is generally in the range of 0.03 GPa to 1 GPa. Even though the surface is altered to expand, no cracking occurs in the case in which the tensile stress is the tensile strength or less. However, when deformation is increased and the tensile stress exceeds the tensile strength, cracking 204 is produced. When the a place that has no defect and has a strong tensile strength withstands deformation and then the cracking 204 is produced at that place, energy accumulated due to the stress is released, and when an impact is generated and sufficient energy toward the surface is present, cracking reaches the surface of the altered layer 203 and cracking 205 is produced. In the case in which energy is further large, a cracked chip 207 flies and attached to the surface of the wafer 4 in the inside of the processing chamber 7 from the surface of the altered layer 203, and this becomes a contamination particles that contaminates the surface of the wafer 4.

Such contamination particles fall from the upper part to the wafer 4 as well as the contamination particles sometimes come from the surface of the component placed below the sample stage 6 or wafer 4. Although the tensile stress produced in the inside is relatively small on the surface of a flat portion, for example, having small surface irregularities, on the surface of the coating, the compressive stress due to fluorination is accumulated. When the degree of accumulation of the stress becomes large, cracking 206 is possibly produced even in the portion having small irregularities.

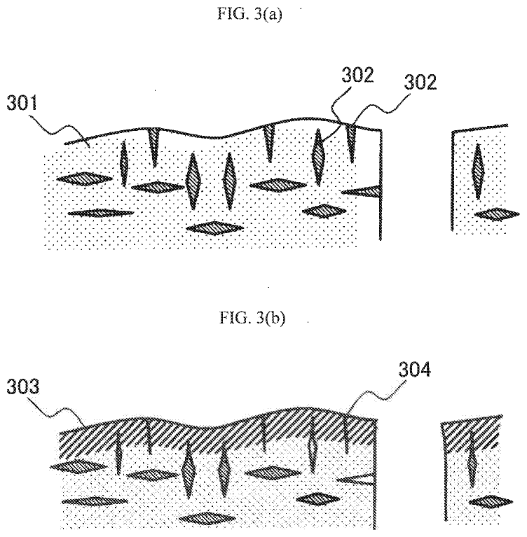

FIGS. 3(a) and 3(b) are longitudinal sectional views schematically showing the outline of the configuration of the coating 140 of the plasma processing apparatus according to the present embodiment. FIG. 3(a) is a view showing the longitudinal section of the coating in the beginning at which the operation is started in which the earth component 40 that is the inner component having the coating formed on the surface is placed in the processing chamber 7 to process the wafer 4. FIG. 3(b) is a view showing the longitudinal section of the coating 140 at a point in time after a point in time when the operation is performed for a period of a predetermined value or more.

On the surface film 142 of the present embodiment, SiO₂ crystal grains that are first material 301 are present in dispersion between Y₂O₃ crystal grains that are second materials 302. Also in the present embodiment, as the conventional technique shown in FIG. 2, the earth component 40 is placed in the inside of the processing chamber 7, and exposed to the plasma 15, and an altered layer 303 including fluoride is formed on the surface of the surface film 142. In the present embodiment, in regard to volume expansion due to the fluorination of the Y₂O₃ crystal grain that is the second material 302, the first material 301 including SiO₂ dispersed in the surface film 142 is volatilized and desorbed (reference sign 304). Thus, compressive stress in the inside of the fluorinated altered layer 303 of the surface film 142 and the accumulation of tensile stress right below the altered layer 303 are suppressed, and the accumulation of the stress and the occurrence of cracking on the surface of the altered layer 303 are suppressed.

Note that in the case of a coating formed by thermal spraying, even though the surface is polished for a mirror surface, irregularities remain on its surface because pores are present in the inside. Thus, even though processing for surface polishing is applied, stress is increased, and particles due to cracking or chipping are generated from the irregularities. In the present embodiment, since the coating 140 is formed on the surface of the side wall of the earth component 40 facing the discharge part in the processing chamber 7 and the coating 140 is not placed right above the wafer 4, a fall of the particles to the wafer because of the gravity of the particle having a van der Waals force of a few micrometers is reduced.

In the coating 140 of the present embodiment formed by plasma spray coating, most of SiO₂ that is not solid-dissolved is present as a second phase or present on the grain boundary of Y₂O₃. SiO₂ is easily volatilized by a fluorine gas more than in solid-dissolved portions, exhibit the effect of relaxing volume expansion quickly. In the present embodiment, since the Y₂O₃ under layer film 141 having a single material Y₂O₃ is placed as the under layer of the surface film 142, the corrosion resistance of the coating 140 can be also improved in addition to the suppression of the cracking of the surface of the coating 140.

The thickness of the under layer film 141 may range from 100 μm to 200 μm. In order to improve corrosion resistance, in the case in which the base material of the earth component 40 is an aluminum alloy, an anodized aluminum layer may be formed further below the under layer film 141.

In the plasma processing apparatus 100 of the present embodiment, the earth component 40 has a metal base material, and the area of the earth component 40 facing the processing chamber 7 is twice the size of the area of the wafer. The voltage of a wall sheath of the inner wall surface of the earth component 40 is the 2.5th power of the ratio of the area of the wafer 4/the area of the inner wall surface of the earth component 40 to Vdc that is the direct current component of a voltage produced on the surface of the wafer 4 by bias forming radio frequency power supplied to the sample stage 6. For example, in the case in which Vdc=0.5 Vpp, the voltage of the wall sheath of the inner wall surface of the earth component 40 is generally 70 V or less.

In ion energy in the collision of charged particles, such as ions, induced on the inner wall surface of the earth component 40 where such a voltage is formed, since the consumption of Y₂O₃ that is the second material 302 that makes the coating 140 due to sputtering is small, it is thought that charged particles in the plasma 15 collide against the inside of a hole (pit) after SiO₂ is desorbed from the surface film 142 and the Y₂O₃ particles are not considerably sputtered from pit as a starting point. Contamination particles or variation over time caused by the accumulation of the sputtered Y atoms on another place are small. By thermal spraying, the deposition of a mixture of oxide is relatively easy.

Since the surface of the coating 140 formed by thermal spraying is not a mirror surface like a polished surface of a sintered material, even though a recess is produced due to the volatilization or desorption of Si, for example, the dimensions of the recess is sufficiently smaller than the size of the irregularities on the surface of the coating 140. Since the coating 140 does not include Al at 1,000 ppm or more, the contamination of the wafer 4 or the surface in the processing chamber 7 due to Al is reduced. Chemical consumption of a component is reduced in which during the step of forming the plasma 15 using a gas including chlorine to process the wafer 4, because most of the plasma resistant material of the coating 140 is not turned into chloride, such as AlCl₃, Al₂Cl₆, and YAlCl₆. Note that according to the investigation of the inventors, in plasma treatment of the wafer 4 including the step of forming the plasma 15 using a gas including a fluorine element, no fluoride (including oxide fluoride) was returned to original oxide, even though discharge was conducted using various gas species.

In the conditions for the process of the wafer 4 in the plasma processing apparatus 100 of the present embodiment, the pressure in the processing chamber 7 during processing of the wafer 4 ranges from 0.1 Pa to 10 Pa. Thus, a substance having a vapor pressure or a sublimation pressure in this range or more is effectively evacuated during processing of the wafer 4 in which the valve 16 is opened and the exhaust system is operated. In the present embodiment, Si that is a material making the altered layer 303 in the upper layer of the surface film 142 is volatilized as a substance, the occurrence of contamination is reduced on the wafer 4 having Si as a material and the film structure including the processing target film on the top surface of the wafer 4.

Since for the ring, for example, that is placed to surround the inner cylinder 41, the sample stage 6, and the wafer 4 on the outer circumferential side of the top surface of the sample stage 6 on which the wafer 4 is placed and that protects the sample stage 6, silica glass is used as a material, the influence on the surface of the wafer 4 or the processing conditions due to the emission of Si as a substance is sufficiently reduced. In the surface film 142 of the coating 140, materials, such as Ti, Cr, Zr, Zn, Hf, and Ta, are not included at 1,000 ppm or more. Thus, it is reduced that these substances are turned into fluoride of a low vapor pressure, the substances remain in the inside of the processing chamber 7, and again attached to the wafer 4 for contamination.

The coating 140 of the present embodiment is also formed on other components having a surface that are placed in the inside of the processing chamber 7 and face the plasma 15 or exposed to contact the plasma 15, except the earth component 40. Similarly, the coating 140 can exert the operation and effect that protect the base material of the component against an attack by the charged particles of the plasma 15 or particles of high reactivity and that reduce and suppress the contamination on the wafer 4 due to the alteration of the coating 140. As methods of forming the coating 140, in addition to APS, aerosol deposition that can form a film on a material which is turned into fine particles in a diameter of 100 nm or less and has a melting point greatly different, suspension plasma thermal spraying that can use a particle raw material in a diameter of 100 nm or less, or the like can be used. With the use of these methods, the first material and the second material are more uniformly closely dispersed also in the material before or after forming the film, and thus smaller cracking and the occurrence of small contamination particles due to the cracking are suppressed.

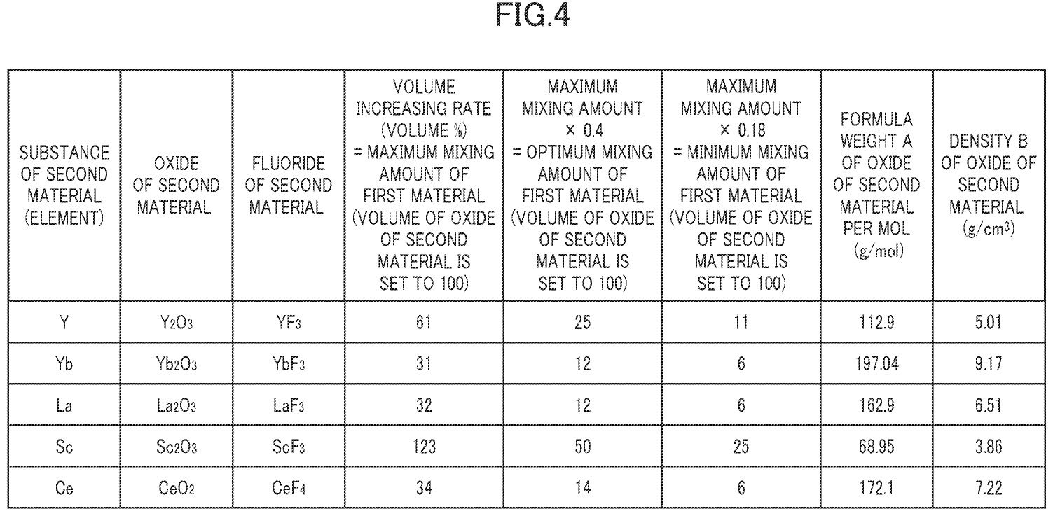

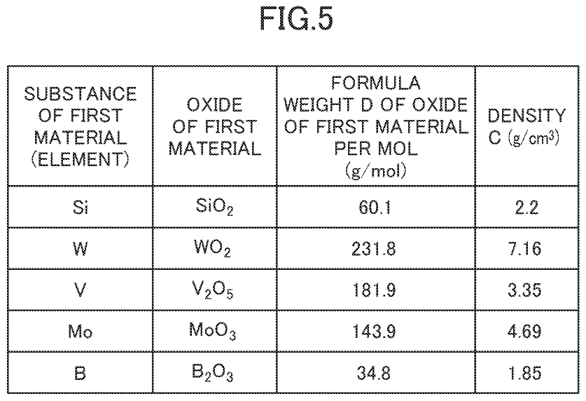

Next, referring to FIGS. 4 and 5, example combinations of materials used for the surface film 142 of the coating 140 in the plasma processing apparatus 100 according to the embodiment will be described. FIG. 4 is a table showing proper ranges of amounts at which the first material having volatility is mixed with a plurality of second materials having non-volatile oxide and non-volatile oxide fluoride in materials that forms the coating of the plasma processing apparatus according to the present embodiment shown in FIG. 1(a). FIG. 5 is a table showing the physical properties of a plurality of first materials that the proper ranges are shown in FIG. 4 in which the pressure of volatile fluoride becomes a vapor pressure greater than a predetermined pressure in the processing chamber.

The mixing ratio of the first and the second materials that make the surface film 142 of the coating 140 of the embodiment is determined from the physical properties of these materials to be mixed. The case will be described in which the first material is Y₂O₃ and the second material is SiO₂.

The second line in FIG. 4 shows the case in which the substance (element) name used as the first material is “Y”. In this case, oxide Y₂O₃ is used as the second material of the surface film 142 formed by plasma spraying. The fluoride of Y is YF3. In the case in which supposing that Y₂O₃ is fully fluorinated and changed to YF3, it is revealed that a volume increase of approximately 61% is generated per Y element. These can be calculated from the mol volume of oxide, the mol volume of fluoride, and the chemical formulas of the oxide and the fluoride.

Depending on the conditions for the process of the wafer 4 using fluorine-contained plasma and oxygen plasma, the material of the surface of the surface film 142 is not fully fluorinated, and the material is sometimes changed to oxyfluoride. For example, in the case of Y₂O₃, Y₂O₃ is sometimes changed to Y₅O₄F₇. In this case, in calculation, the volume is increased by 11% per Y element, which is about 0.18 times the volume increase rate in the case in which Y₂O₃ is fully fluorinated.

Since a part of oxygen in the entire oxide is by fluorine, fluorination is started. However, as the number of fluorine bonded to one metal atom is more increased, binding energy for more fluorination is reduced, and thus the progress of fluorination is slowed. On the surface that expands and increases in compressive stress, the progress is further slowed, and the progress substantially stops before full fluorination. In this case, according to the investigation of the inventors, in the embodiment, the rate of increasing deposition due to fluorination was about 0.37 times the case in which the second material on the surface of the surface film 142 is fully fluorinated.

From this, in the present embodiment, as the rate of mixing SiO₂ as the first material with Y₂O₃ as the second material, a rate was selected in a range in which the rate was in the range from 0.18 times to 0.4 times the rate of increasing the volume determined from calculation in the case in which the element of the second material was fully fluorinated. It is estimated that with the mixing rate (ratio) within the range, energy of progress of fluorination is moderately reduced, the energy stands against the compressive stress on the surface that suppresses the progress of fluorination for stabilization, and thus cracking is suppressed. In the case in which the rate of SiO₂ is smaller than this range, the tensile stress in the inside or compressive stress on the surface layer is increased due to the fluorination expansion of Y₂O₃, and the occurrence of cracking or removal of grain is increased.

On the conditions of processing the wafer 4, the amount of the first material at which the first material of the surface film 142 is fully fluorinated is the upper limit of the mixing ratio of the first material. When the first material is mixed at the amount or more, even though the first material is fluorinated and the volume expands, a volume more than that volume is volatilized, resulting in generating gaps.

The weight ratio of the first and the second materials in the mixed material can be determined from the following Equation based on numerical values shown in FIGS. 4 and 5.

The amount of the oxide of the second material:the amount of the oxide of the first material=A:[A/B×{the mixing amount of the oxide of the first material (the volume of the oxide of the second material is 100)/100}]×C Here,

(FIG. 4, A=the formula weight of the oxide per mole of the element of the second material in FIG. 4

B=the density of the oxide of the second material in FIG. 4

the mixing amount of the oxide of the first material (the volume of the oxide of the second material is 100) is shown in FIG. 4

FIG. 5, C=the density of the oxide of the first material per mole of the element of the first material

The method that determines the mixing rate of the first and the second materials of the surface film 142 from the physical property value can be similarly applied to the case of the other types of substances (elements) shown in FIGS. 4 and 5 that show these materials. For example, in the case in which the second material is Yb₂O₃ and the first material is WO₂, the mixing rate of oxide can be determined to Yb₂O₃:WO₂=100:6 by the volume ratio. From the Equation, the weight ratio of the materials can be set to Yb₂O₃:WO₂=197:9.

The coating 140 made of the materials in this case can also relax an increase in the surface film 142 due to an increase in the volume of the crystal grain or an increase in the dimensions of the fluorinated altered layer 303 due to the fluorination of Yb₂O₃ because WF₆ is volatilized from the surface film 142, which is formed from a gas species including the fluorine in the processing chamber 7 and the pressure conditions in the process of the wafer 4 conducted in the plasma processing apparatus 100 according to the embodiment, and cracking or the generation of contamination particles on the surface of the surface film 142 is suppressed. In the case of this example, since the atomic weight of the second material is heavy and close to the first atom, and the improvement of sputtering resistance to the ion injection from the plasma 15 is expected.

For elements other than ones shown in FIG. 5, in the case in which the vapor pressure or sublimation pressure of these elements, such as Cr, Ir, Hf, Nb, and Ta, are higher than the pressure in the processing chamber 7 in the process of the wafer 4 in the plasma processing apparatus 100, the elements can be volatilized from the surface of the coating 140, and the mechanical strength of fluoride is relatively small. Thus, the stress is not accumulated in the inside of the surface film 142, providing the effect of preventing cracking. For example, in the case in which the processing target film of the film structure, which is formed in advance on the top surface of the wafer 4, for forming the circuit structure of a semiconductor device includes at least any one of Ti, Hf, and Ta, these elements may be included in the surface film 142 as the first materials.

Even though a plurality of elements in FIG. 4 and/or other oxides of 3A group are used as a non-volatile second material, the operation and effect similar to those of the embodiment can be exerted. Even though a plurality of elements having the properties is mixed as the volatile second material, the similar effect can be exerted.

In the embodiment, the description is made on the coating 140 formed on the surface of the component, such as the earth component 40, that faces the plasma 15 and is placed in the inside of the processing chamber 7. However, even though the material having the first and the second materials mixed is applied to the place that constitutes the surface of the ceramics component formed as a sintered material, the similar operation and effect can be exerted. As the first and the second materials or the material of the surface film 142, the material is not limited to a ceramics material. Other oxide materials, such as glass, can exert similar effect as well.

Note that the present invention is not limited to the foregoing embodiment, which includes various example modifications. For example, the foregoing embodiment describes the present invention in detail for easy understanding. The present invention is not necessarily limited to the same ones as all the use conditions described above. A part of the configuration of an embodiment can be replaced by the configuration of another embodiment. The ratios are not limited to example ratios described in the embodiment.

### REFERENCE SIGNS LIST

1 . . . vacuum chamber
2 . . . shower plate
3 . . . window component
4 . . . wafer
6 . . . sample stage
7 . . . processing chamber
8 . . . gap
9 . . . gas inlet hole
11 . . . roughing vacuum pump
12 . . . turbo molecule pump
13 . . . matching circuit
14 . . . radio frequency power supply
15 . . . plasma
16 . . . valve
20 . . . power supply
21 . . . waveguide
22, 23 . . . coil
40 . . . earth component
41 . . . inner cylinder
42 . . . side wall component
100 . . . plasma processing apparatus
140 . . . coating
141 . . . under layer film
142 . . . surface film

1. A plasma processing apparatus that processes a wafer which is a processing target placed in a processing chamber in an inside of a vacuum chamber using plasma formed from a processing gas supplied to an inside of the processing chamber,
wherein: a surface of a component that is placed in the inside of the processing chamber and faces the plasma is made of a dielectric material; and
the dielectric material includes
a first material that combines with the supplied processing gas and is volatilized and
a second material that combines with the processing gas to produce a non-volatile compound, a volume of the non-volatile compound being increased before the combination.

2. The plasma processing apparatus according to claim 1,
wherein the dielectric material includes the first material by an amount corresponding to a volume increased from a volume before the combination of the compound of the second material.

3. The plasma processing apparatus according to claim 1,
wherein: the first material includes Si; and
the second material includes Y.

4. An inner component of a plasma processing apparatus, the inner component being placed in an inside of a processing chamber of the plasma processing apparatus that processes a wafer that is a processing target placed in the processing chamber in an inside of a vacuum chamber using plasma formed from a processing gas supplied to the inside of the processing chamber,
wherein: a surface of the inner component that faces the plasma is made of a dielectric material; and
the dielectric material includes
a first material that combines with the supplied processing gas and is volatilized and
a second material that combines with the processing gas to produce a non-volatile compound, a volume of the non-volatile compound being increased before the combination.

5. The inner component of a plasma processing apparatus according to claim 4,
wherein the dielectric material includes the first material by an amount corresponding to a volume increased from a volume before the combination of the compound of the second material.

6. The inner component of a plasma processing apparatus according to claim 4,
wherein: the first material includes Si; and
the second material includes Y

7. A manufacturing method for an inner component that is placed in a processing chamber in an inside of a vacuum chamber of a plasma processing apparatus that processes a wafer that is a processing target using plasma formed from a processing gas supplied to an inside of the processing chamber,
wherein on a surface of the inner component, a dielectric material is formed in advance, the dielectric material including
a first material that combines with the supplied processing gas and is volatilized and
a second material that combines with the processing gas to produce a non-volatile compound, a volume of the non-volatile compound being increased before the combination.

8. A manufacturing method for an inner component that is placed in a processing chamber in an inside of a vacuum chamber of a plasma processing apparatus that processes a wafer that is a processing target using plasma formed from a processing gas supplied to an inside of the processing chamber,
wherein: on a surface of the inner component, a dielectric material is formed in advance, the dielectric material including
a first material that combines with the supplied processing gas and is volatilized and
a second material that combines with the processing gas to produce a non-volatile compound, a volume of the non-volatile compound being increased before the combination; and
before the wafer is processed, a step of exposing a surface of the inner component to the plasma formed by supplying the processing gas to the inside of the processing chamber for a predetermined time to alter the surface.

9. The manufacturing method for an inner component of a plasma processing apparatus according to claim 8,
wherein the dielectric material includes the first material by an amount corresponding to a volume increased from a volume before the combination of the compound of the second material.
